(19) United States
(12) Patent Application Publication
(10) Pub. No.: US 2024/0345477 A1
(43) Pub. Date: Oct. 17, 2024

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Dong Wan RYU, Suwon-si (KR); Young Keun KIM, Suwon-si (KR); Seol Hee LIM, Suwon-si (KR); Soobin LIM, Suwon-si (KR); Sukil KANG, Suwon-si (KR)

(21) Appl. No.: 18/587,235

(22) Filed: Feb. 26, 2024

(30) Foreign Application Priority Data
Apr. 14, 2023 (KR) 10-2023-0049583

(51) Int. Cl. G03F 7/004; G03F 7/027; G03F 7/20

(52) U.S. Cl. CPC G03F 7/0042; G03F 7/0048; G03F 7/027; G03F 7/2006

(57) ABSTRACT

Disclosed are a semiconductor photoresist composition including an organometallic compound represented by Chemical Formula 1, and a solvent, a method of forming patterns using the same.

### CROSS-REFERENCE TO RELATED APPLICATION

The present application claims priority to and the benefit of Korean Patent Application No. 10-2023-0049583, filed on Apr. 14, 2023, in the Korean Intellectual Property Office, the entire disclosure of which is incorporated by reference herein.

### BACKGROUND

### 1. Field

Embodiments of this disclosure relate to a semiconductor photoresist composition and a method of forming patterns using the same.

### 2. Description of the Related Art

EUV (extreme ultraviolet) lithography is paid attention to as one important technology for manufacturing a next generation semiconductor device. The EUV lithography is a pattern-forming technology using an EUV ray having a wavelength of about 13.5 nm as an exposure light source. Utilizing EUV lithography, an extremely fine pattern (e.g., less than or equal to about 20 nm) may be formed in an exposure process during a manufacture of a semiconductor device.

Extreme ultraviolet (EUV) lithography is realized through development of compatible photoresists which can be performed at a spatial resolution of less than or equal to about 16 nm. Currently, efforts to satisfy insufficient specifications of chemically amplified (CA) photoresists such as a resolution, a photospeed, and feature roughness (or also referred to as a line edge roughness or LER) for the next generation device are being made.

An intrinsic image blurring due to an acid catalyzed reaction in these polymer-type photoresists limits a resolution in small feature sizes, which has persisted in electron beam (e-beam) lithography for a long time. The chemically amplified (CA) photoresists are designed for high sensitivity, but because their generally used elemental makeups reduce light absorbance of the photoresists at a wavelength of about 13.5 nm and thus decrease their sensitivity, the chemically amplified (CA) photoresists may partially have more difficulties under an EUV exposure.

The CA photoresists may have difficulties in the small feature sizes due to roughness issues, and line edge roughness (LER) of the CA photoresists experimentally turns out to be increased, as a photospeed is decreased partially due to features of acid catalyst processes. Accordingly, a novel high-performance photoresist is desired in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition is mainly used for negative tone patterning having resistance against removal by a developer composition due to chemical modification through nonchemical amplification mechanism. The inorganic composition contains an inorganic element having a higher EUV absorption rate than hydrocarbons and thus may secure sensitivity through the nonchemical amplification mechanism and, is less sensitive with respect to a stochastic effect and thus has low line edge roughness and a small number of defects.

Inorganic photoresists based on peroxopolyacids of tungsten mixed together with tungsten, niobium, titanium, and/or tantalum have been reported as radiation sensitive materials for patterning.

These materials are effective for patterning large pitches for a bilayer configuration as far ultraviolet (deep UV), X-ray, and electron beam sources. More recently, if cationic hafnium metal oxide sulfate (HfSOx) materials along with a peroxo complexing agent has been used to image a 15 nm half-pitch (HP) through projection EUV exposure, impressive performance has been obtained. Such systems exhibit the highest performance of a non-CA photoresist and has a practicable photospeed near to a condition for an EUV photoresist. However, the hafnium metal oxide sulfate materials having the peroxo complexing agent have a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of about 25 wt % and/or the like.

In recent years, active research has been conducted relating to molecules containing tin that have excellent absorption of extreme ultraviolet rays. As for an organotin polymer among them, an alkyl ligand is dissociated by light absorption or secondary electrons produced thereby and crosslinked with adjacent chains through an oxo bond and thus enables the negative tone patterning which may not be removed by an organic developer. This organotin polymer exhibits greatly improved sensitivity as well as maintains a resolution and line edge roughness, but it would be beneficial for the patterning characteristics to be additionally improved for commercial availability.

### SUMMARY

Some embodiments provide a semiconductor photoresist composition that exhibits excellent sensitivity and has improved stability and coating properties.

Some embodiments provide a method of forming patterns using the semiconductor photoresist composition.

A semiconductor photoresist composition according to some embodiments includes an organometallic compound represented by Chemical Formula 1 and a solvent.

(R¹)ₙ-M-Xₘ Chemical Formula 1

In Chemical Formula 1, R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),

M is a metal selected from Groups 2 to 16 of the periodic table,

n and m are each independently one selected from integers from 1 to 6,

2≤n+m≤6, and

X is a ligand represented by at least one selected from Chemical Formula 1A and Chemical Formula 1B,

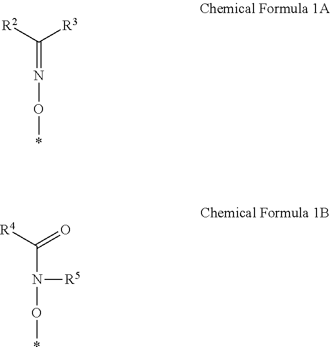

wherein, in Chemical Formula 1A and Chemical Formula 1B, R², R³, and R⁵ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C1 to C30 acyl group, or a combination thereof,

R² and R³ are independently present or combined with each other to form a ring,

R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C6 to C30 aryloxy group, or a combination thereof, and * is a linking point with M.

The organometallic compound may be represented by Chemical Formula 2 or Chemical Formula 3.

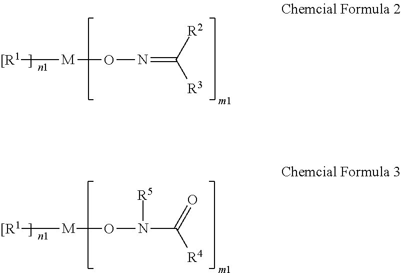

In Chemical Formula 2 and Chemical Formula 3, R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),

M is a metal selected from Groups 2 to 16 of the periodic table,

n1 and m1 are each independently one selected from integers from 1 to 5,

2≤n1+m1≤6, and

R², R³, and R⁵ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C1 to C30 acyl group, or a combination thereof.

R² and R³ are independently present or combined with each other to form a ring.

R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C6 to C30 aryloxy group, or a combination thereof.

The n+m (e.g., n1+m1) may be an integer of 4 to 6.

M may be Sn or Sb.

R², R³, and R⁵ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C2 to C30 heteroaryl group, a substituted or unsubstituted C1 to C20 alkoxy group, a substituted or unsubstituted C6 to C30 aryl group, a substituted or unsubstituted C1 to C30 acyl group, or a combination thereof, and R² and R³ are independently present or combined with each other to form a ring.

R⁴ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C2 to C30 heteroaryl group, a substituted or unsubstituted C1 to C20 alkoxy group, a substituted or unsubstituted C6 to C30 aryl group, a substituted or unsubstituted C1 to C30 aryloxy group, or a combination thereof.

R¹ may be a substituted or unsubstituted C1 to C20 alkyl group, a substituted or unsubstituted C3 to C20 cycloalkyl group, or a substituted or unsubstituted C6 to C30 aryl group,

R², R³, and R⁵ may each independently be hydrogen, a substituted or unsubstituted C1 to C20 alkyl group, or a substituted or unsubstituted C3 to C20 cycloalkyl group, and

R⁴ may be a substituted or unsubstituted C1 to C20 alkyl group, or a substituted or unsubstituted C3 to C20 cycloalkyl group.

R¹ may be a substituted or unsubstituted C3 to C20 branched alkyl group.

R¹ may be an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

The organometallic compound may be one selected from compounds listed in Group 1.

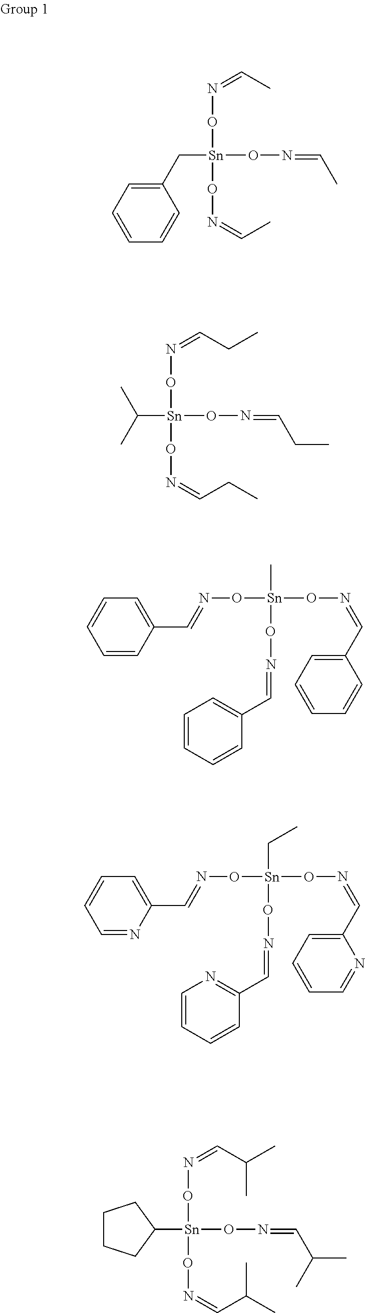

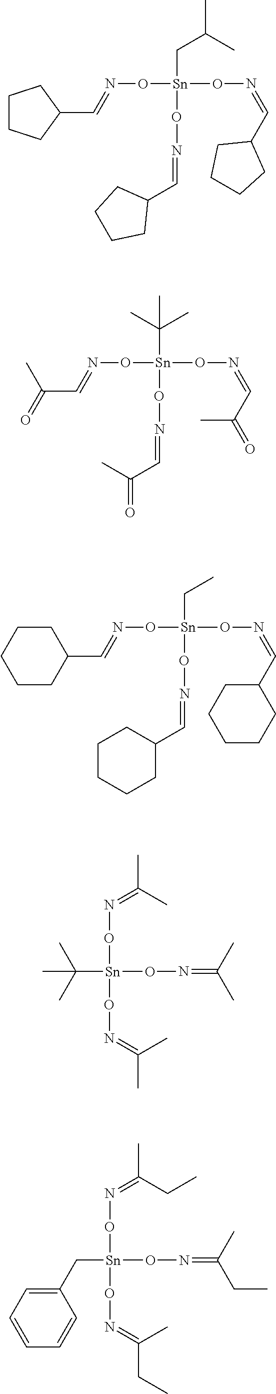 [SMILES: CC(C)[CH2][Sn]([O]N=CC1CCCC1)([O]/N=C\C1CCCC1)[O]/N=C/C1CCCC1 ; CC(=O)C=N[O][Sn]([O]/N=C\C(C)=O)([O]/N=C/C(C)=O)[C](C)(C)C ; C[CH2][Sn]([O]N=CC1CCCCC1)([O]/N=C\C1CCCCC1)[O]/N=C/C1CCCCC1 ; CC(C)=N[O][Sn]([O]N=C(C)C)([O]N=C(C)C)[C](C)(C)C ; CCC(C)=N[O][Sn]([CH2]c1ccccc1)([O]/N=C(/C)CC)[O]/N=C(\C)CC]

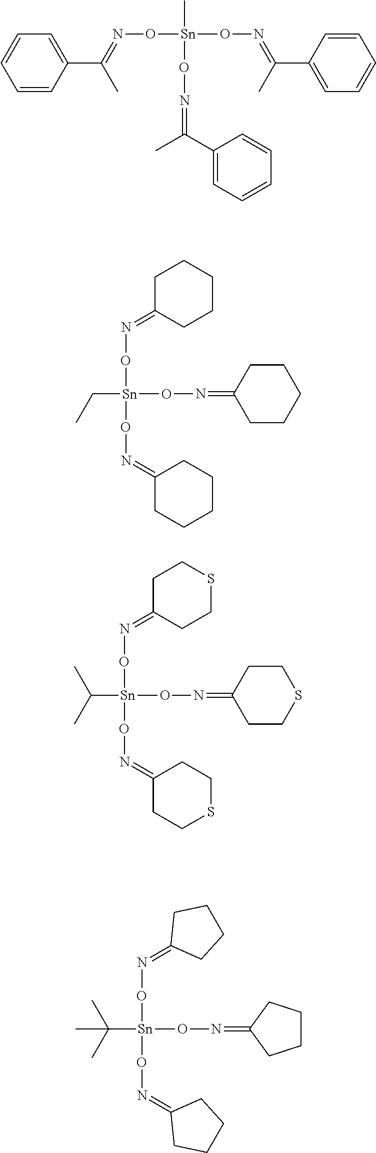

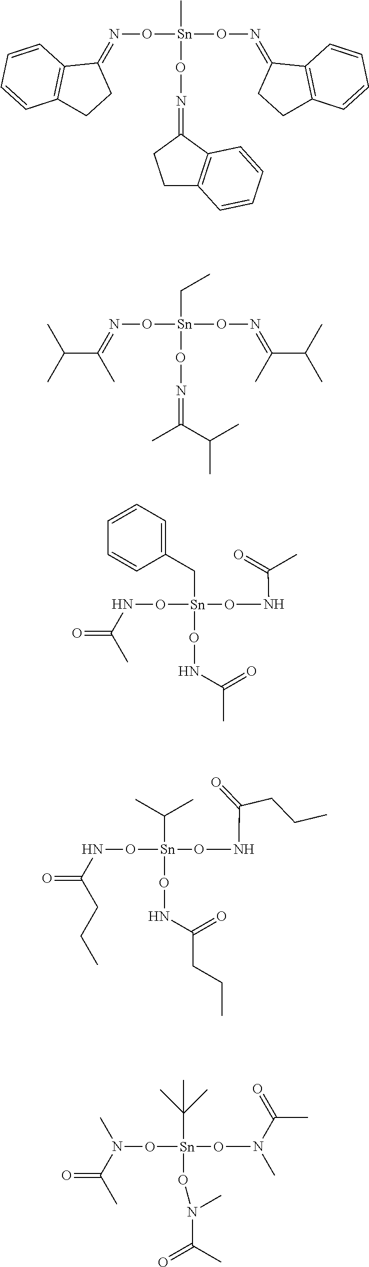 [SMILES: [CH3][Sn]([O]N=C1CCc2ccccc21)([O]/N=C1\CCc2ccccc21)[O]/N=C1\CCc2ccccc21 ; C[CH2][Sn]([O]N=C(C)C(C)C)([O]/N=C(\C)C(C)C)[O]/N=C(\C)C(C)C ; CC(=O)N[O][Sn]([CH2]c1ccccc1)([O]NC(C)=O)[O]NC(C)=O ; CCCC(=O)N[O][Sn]([O]NC(=O)CCC)([O]NC(=O)CCC)[CH](C)C ; CC(=O)N(C)[O][Sn]([O]N(C)C(C)=O)([O]N(C)C(C)=O)[C](C)(C)C]

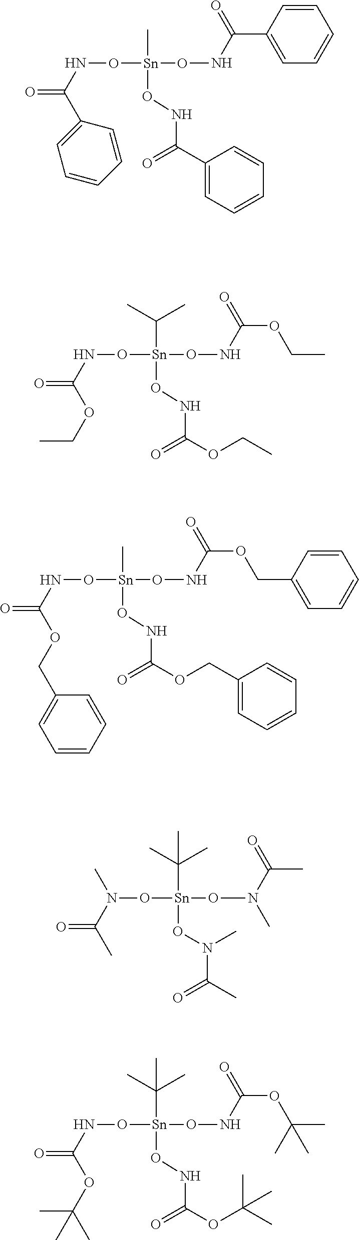 [SMILES: [CH3][Sn]([O]NC(=O)c1ccccc1)([O]NC(=O)c1ccccc1)[O]NC(=O)c1ccccc1 ; CCOC(=O)N[O][Sn]([O]NC(=O)OCC)([O]NC(=O)OCC)[CH](C)C ; [CH3][Sn]([O]NC(=O)OCc1ccccc1)([O]NC(=O)OCc1ccccc1)[O]NC(=O)OCc1ccccc1 ; CC(=O)N(C)[O][Sn]([O]N(C)C(C)=O)([O]N(C)C(C)=O)[C](C)(C)C ; CC(C)(C)OC(=O)N[O][Sn]([O]NC(=O)OC(C)(C)C)([O]NC(=O)OC(C)(C)C)[C](C)(C)C]

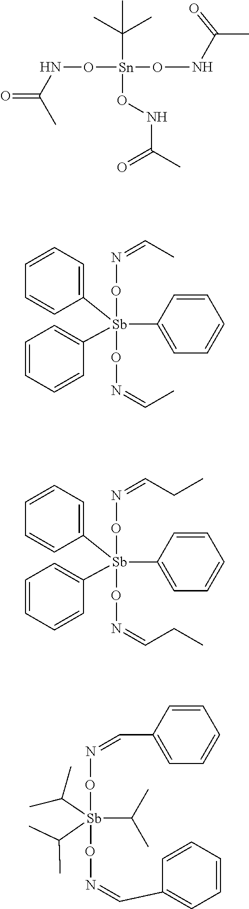

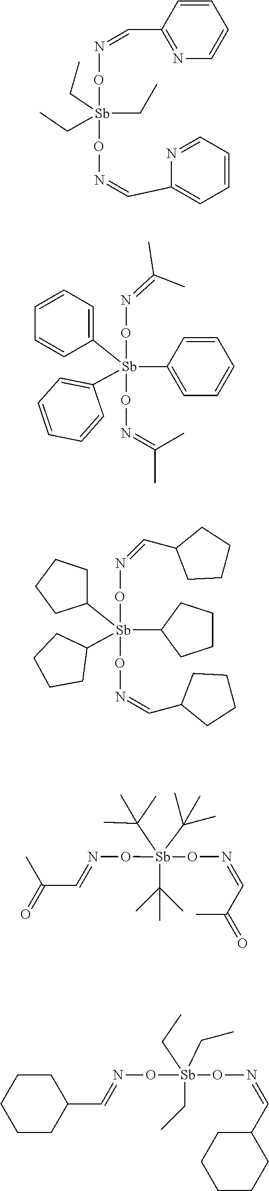

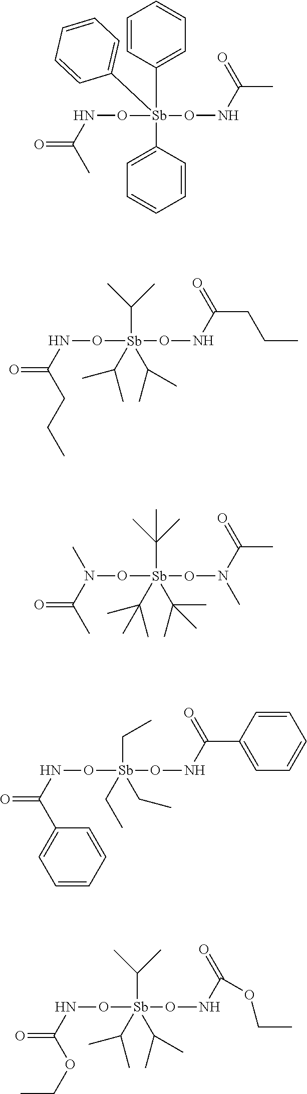

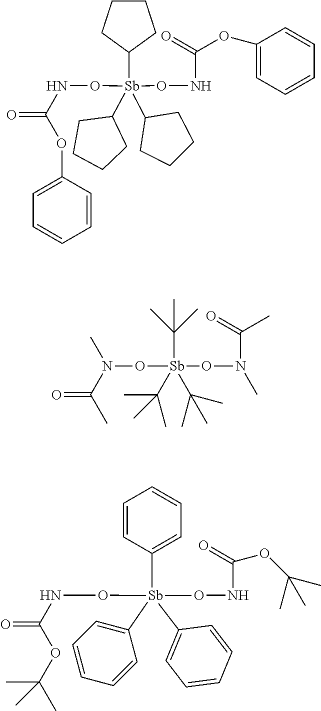

Based on 100 wt % of the semiconductor photoresist composition, the organometallic compound may be included in an amount of about 1 wt % to about 30 wt %.

The semiconductor photoresist composition may further include an additive of a surfactant, a crosslinking agent, a leveling agent, or a combination thereof.

A method of forming patterns according to some embodiments includes forming an etching-objective layer on a substrate, coating the semiconductor photoresist composition on the etching-objective layer to form a photoresist layer, patterning the photoresist layer to form a photoresist pattern, and etching the etching-objective layer using the photoresist pattern as an etching mask.

The photoresist pattern may be formed using light having a wavelength of about 5 nm to about 150 nm.

The photoresist pattern may have a width of about 5 nm to about 100 nm.

The semiconductor photoresist composition according to some embodiments may provide a photoresist pattern having improved storage stability, coating properties, and sensitivity.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-5 are cross-sectional views for explaining a method of forming patterns using a semiconductor photoresist composition according to some embodiments.

### DETAILED DESCRIPTION

Hereinafter, embodiments of the present disclosure will be described in more detail, referring to the accompanying drawings. However, in the description of the present disclosure, descriptions for already known functions and/or components will be omitted for clarifying the gist of the present disclosure.

In order to clearly describe the present disclosure, parts which are not related to the description are omitted, and the same reference numeral refers to the same or like components, throughout the specification. In some embodiments, because the size and the thickness of each component shown in the drawing are optionally represented for convenience of the description, the present disclosure is not limited to the illustration.

In the drawings, the thickness shown may be enlarged to clearly express the various layers and regions. Also, in the drawings, the thicknesses of some layers and regions may be exaggerated for convenience of description. It will be understood that if an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxy group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a combination thereof. “Unsubstituted” refers to non-replacement of a hydrogen atom by another substituent and remaining of the hydrogen atom.

As used herein, if a definition is not otherwise provided, “alkyl group” refers to a linear or branched aliphatic hydrocarbon group. The alkyl group may be “a saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, a C1 to C5 alkyl group, or a C1 to C4 alkyl group. For example, the C1 to C4 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if a definition is not otherwise provided, “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As used herein, “aryl group” refers to a substituent in which all atoms in the cyclic substituent have a p-orbital and these p-orbitals are conjugated and may include a monocyclic or fused ring polycyclic (e.g., rings sharing adjacent pairs of carbon atoms) functional group.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

In the chemical formulas described herein, t-Bu refers to a tert-butyl group.

Hereinafter, a semiconductor photoresist composition according to some embodiments is described.

The semiconductor photoresist composition according to some embodiments of the present disclosure includes an organometallic compound represented by Chemical Formula 1 and a solvent.

(R¹)ₙ-M-Xₘ Chemical Formula 1

In Chemical Formula 1,

R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),

M is a metal selected from Groups 2 to 16 of the periodic table,

n and m are each independently one selected from integers from 1 to 6,

2≤n+m≤6, and

X is a ligand represented by at least one selected from Chemical Formula 1A and Chemical Formula 1B,

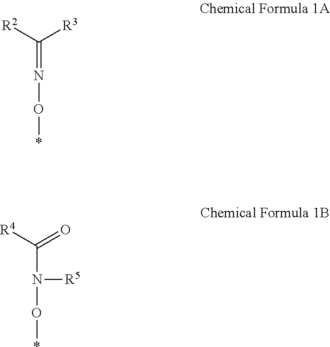

wherein, in Chemical Formula 1A and Chemical Formula 1B,

R², R³, and R⁵ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C1 to C30 acyl group, or a combination thereof,

R² and R³ are independently present or combined with each other to form a ring,

R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C6 to C30 aryloxy group, or a combination thereof, and * is a linking point with M.

The organometallic compound coordinates an N-containing ligand having an alpha effect to the metal, so that a bond between the metal and the ligand is strengthened due to the electron-donating property of N, and storage stability against moisture may be improved.

In some embodiments, compared to the general tetravalently coordinated monomolecular form, the coordination number of Sn is satisfied due to the additional coordination bond and the Sn atoms are structurally hidden (e.g., are protected from further reaction), and thus moisture stability is improved and an aggregation phenomenon is prevented or reduced. As a result, it can be coated in an amorphous form without using additives during spin coating, thereby improving sensitivity and coating properties.

For example, the organometallic compound may be represented by Chemical Formula 2 or Chemical Formula 3.

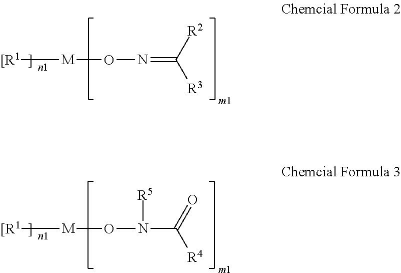

In Chemical Formula 2 and Chemical Formula 3, R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, or —R^{a}—O—R^{b} (wherein R^{a} is a substituted or unsubstituted C1 to C20 alkylene group and R^{b} is a substituted or unsubstituted C1 to C20 alkyl group), M is a metal selected from Groups 2 to 16 of the periodic table,

n1 and m1 are each independently one selected from integers from 1 to 5,

2≤n1+m1≤6, and

R², R³, and R⁵ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C1 to C30 acyl group, or a combination thereof.

R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C6 to C30 aryloxy group, or a combination thereof.

For example, n+m (e.g., n1+m1) may be one selected from integers from 3 to 6.

For example, n+m (e.g., n1+m1) may be one selected from integers from 4 to 6.

M may be Sn or Sb.

R², R³, and R⁵ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C2 to C30 heteroaryl group, a substituted or unsubstituted C1 to C20 alkoxy group, a substituted or unsubstituted C1 to C30 acyl group, or a combination thereof, and R² and R³ are independently present or combined with each other to form a ring.

R⁴ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C2 to C30 heteroaryl group, a substituted or unsubstituted C1 to C20 alkoxy group, a substituted or unsubstituted C6 to C30 aryl group, a substituted or unsubstituted C1 to C30 aryloxy group, or a combination thereof.

R¹ may be a substituted or unsubstituted C1 to C20 alkyl group, a substituted or unsubstituted C3 to C20 cycloalkyl group, or a substituted or unsubstituted C6 to C30 aryl group,

R², R³, and R⁵ may each independently be hydrogen, a substituted or unsubstituted C1 to C20 alkyl group, or a substituted or unsubstituted C3 to C20 cycloalkyl group,

R⁴ may be a substituted or unsubstituted C1 to C20 alkyl group, or a substituted or unsubstituted C3 to C20 cycloalkyl group.

R¹ may be a substituted or unsubstituted C3 to C20 branched alkyl group.

R¹ may be an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

The organometallic compound may be selected from compounds listed in Group 1.

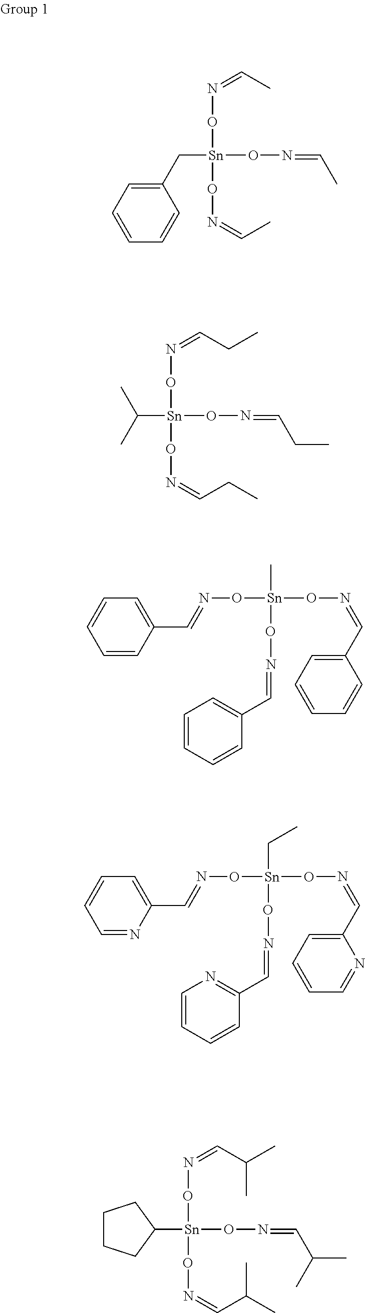

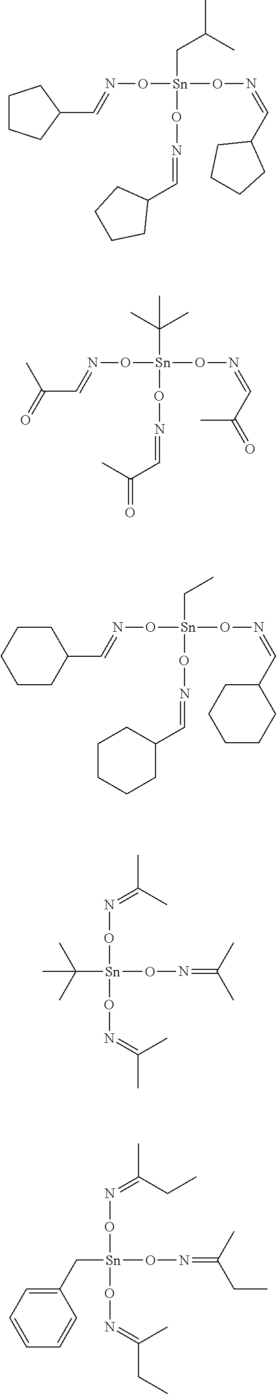 [SMILES: CC(C)[CH2][Sn]([O]N=CC1CCCC1)([O]/N=C\C1CCCC1)[O]/N=C/C1CCCC1 ; CC(=O)C=N[O][Sn]([O]/N=C\C(C)=O)([O]/N=C/C(C)=O)[C](C)(C)C ; C[CH2][Sn]([O]N=CC1CCCCC1)([O]/N=C\C1CCCCC1)[O]/N=C/C1CCCCC1 ; CC(C)=N[O][Sn]([O]N=C(C)C)([O]N=C(C)C)[C](C)(C)C ; CCC(C)=N[O][Sn]([CH2]c1ccccc1)([O]/N=C(/C)CC)[O]/N=C(\C)CC]

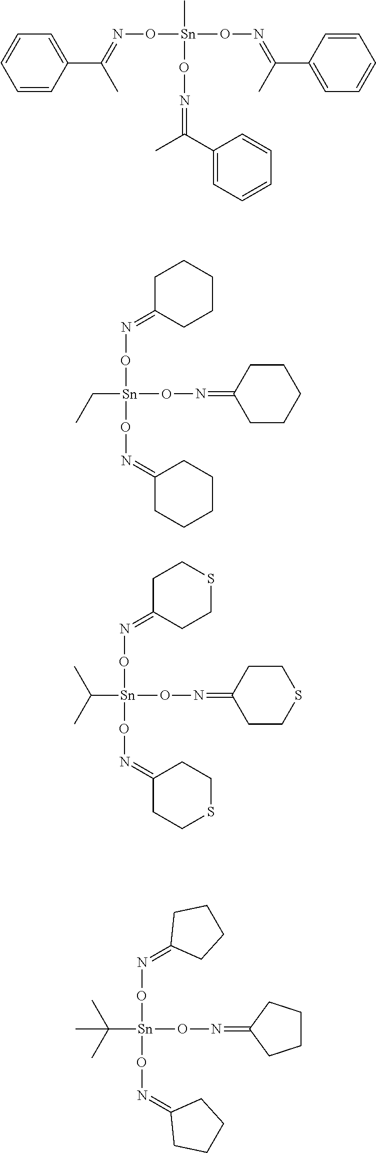

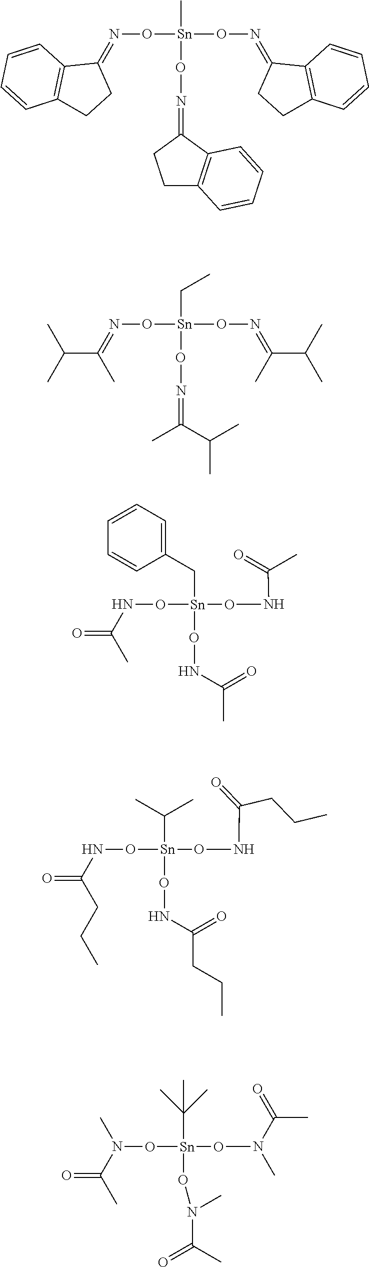 [SMILES: [CH3][Sn]([O]N=C1CCc2ccccc21)([O]/N=C1\CCc2ccccc21)[O]/N=C1\CCc2ccccc21 ; C[CH2][Sn]([O]N=C(C)C(C)C)([O]/N=C(\C)C(C)C)[O]/N=C(\C)C(C)C ; CC(=O)N[O][Sn]([CH2]c1ccccc1)([O]NC(C)=O)[O]NC(C)=O ; CCCC(=O)N[O][Sn]([O]NC(=O)CCC)([O]NC(=O)CCC)[CH](C)C ; CC(=O)N(C)[O][Sn]([O]N(C)C(C)=O)([O]N(C)C(C)=O)[C](C)(C)C]

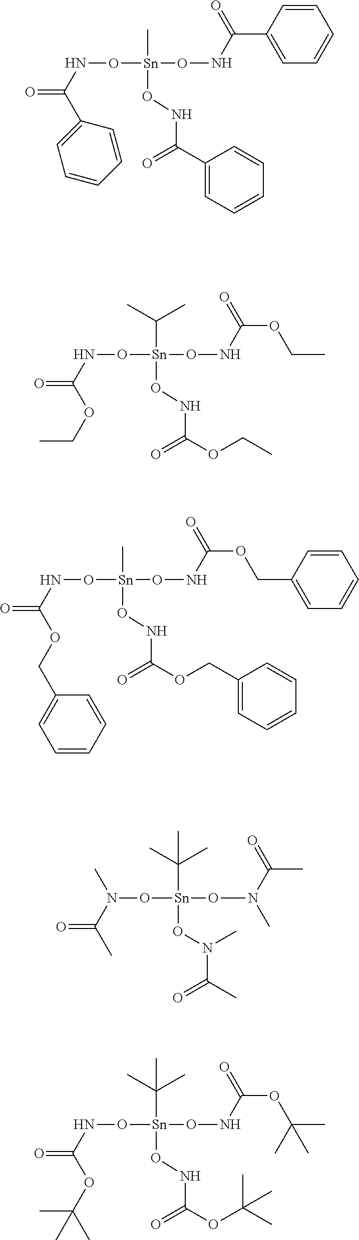 [SMILES: [CH3][Sn]([O]NC(=O)c1ccccc1)([O]NC(=O)c1ccccc1)[O]NC(=O)c1ccccc1 ; CCOC(=O)N[O][Sn]([O]NC(=O)OCC)([O]NC(=O)OCC)[CH](C)C ; [CH3][Sn]([O]NC(=O)OCc1ccccc1)([O]NC(=O)OCc1ccccc1)[O]NC(=O)OCc1ccccc1 ; CC(=O)N(C)[O][Sn]([O]N(C)C(C)=O)([O]N(C)C(C)=O)[C](C)(C)C ; CC(C)(C)OC(=O)N[O][Sn]([O]NC(=O)OC(C)(C)C)([O]NC(=O)OC(C)(C)C)[C](C)(C)C]

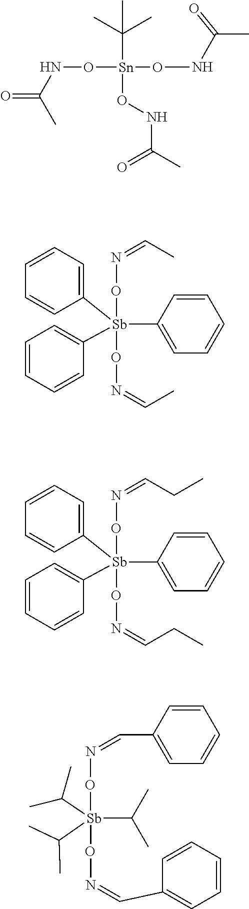

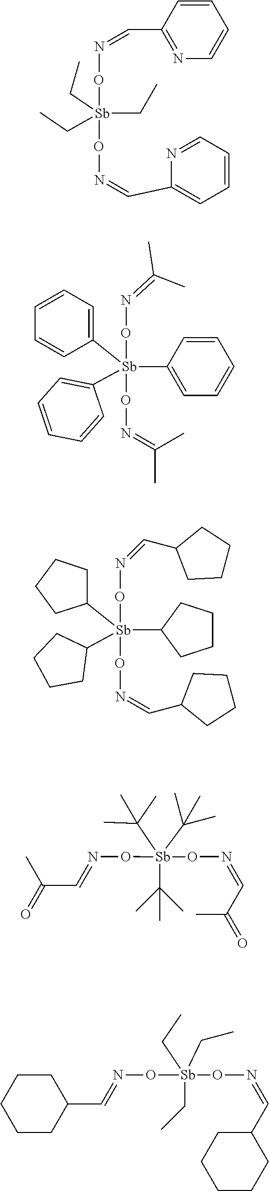

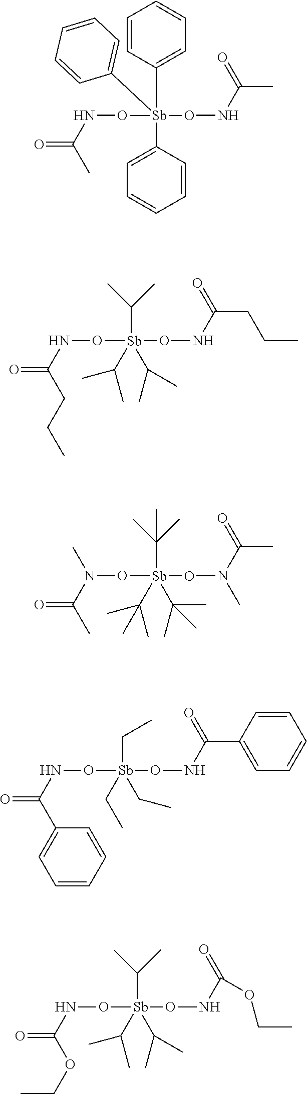

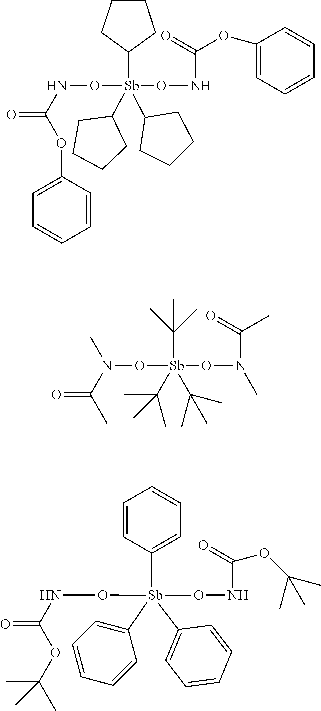

The organometallic compound may strongly absorb extreme ultraviolet light at about 13.5 nm and may have excellent sensitivity to light having high energy.

In the semiconductor photoresist composition according to some embodiments, based on 100 wt % of the semiconductor photoresist composition, the organometallic compound may be included in an amount of about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt %, but is not limited to thereto. If the organometallic compound is included in an amount within the above ranges, storage stability and etch resistance of the semiconductor photoresist composition are improved, and resolution characteristics are improved.

As the semiconductor photoresist composition according to some embodiments of the present disclosure may have excellent sensitivity and pattern formation properties due to the aforementioned organometallic compound.

The solvent included in the semiconductor photoresist composition according to some embodiments may be an organic solvent. The solvent may be, for example, aromatic compounds (e.g., xylene, toluene, etc.), alcohols (e.g., 4-methyl-2-pentanol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), or a mixture thereof, but is not limited thereto.

In some embodiments, the semiconductor photoresist composition may further include a resin in addition to the organometallic compound and the solvent.

The resin may be a phenol-based resin including at least one or more aromatic moieties of Group 2.

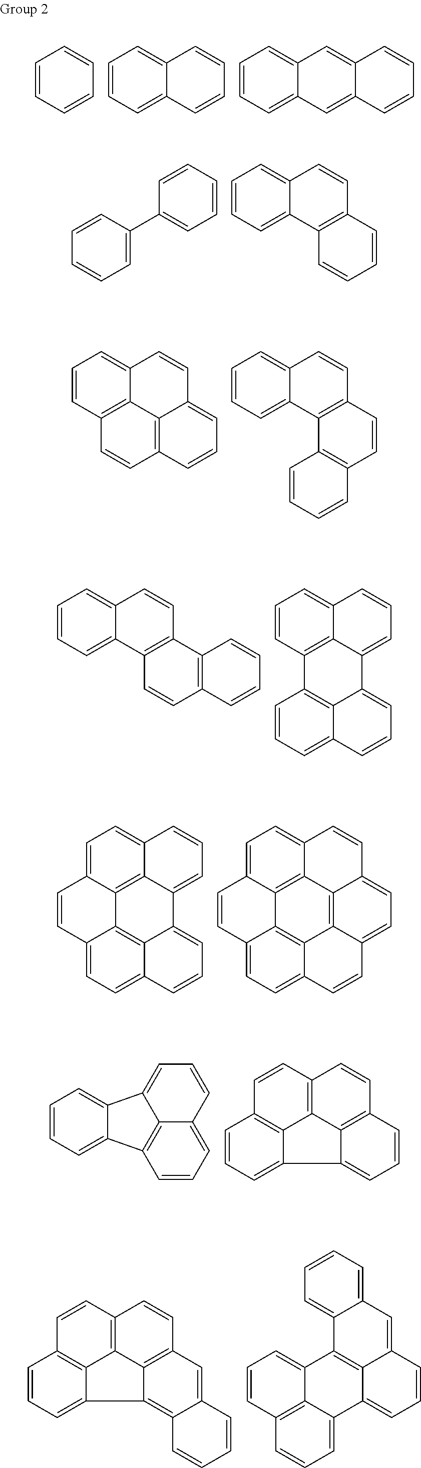

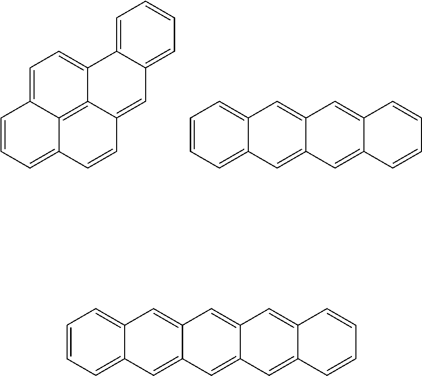

The resin may have a weight average molecular weight of about 500 to about 20,000.

The resin may be included in an amount of about 0.1 wt % to about 50 wt % based on a total amount of the semiconductor photoresist composition.

If the resin is included within the amount range herein, it may have excellent etch resistance and heat resistance.

The semiconductor photoresist composition according to some embodiments may be composed of the aforementioned organometallic compound, a solvent, and a resin. However, the semiconductor photoresist composition according to the above-described embodiment may further include additives as needed. Examples of the additive may include a surfactant, a crosslinking agent, a leveling agent, organic acid, a quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, and/or a polymer-based crosslinking agent, but is not limited thereto. It may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, and/or methoxymethylated thiourea, and/or the like.

The leveling agent may be used for improving coating flatness during printing and may be any suitable leveling agent generally used in the art.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl (p-triyl) amine, methyl diphenyl amine, triphenyl amine, phenylenediamine, naphthylamine, diaminonaphthalene, or a combination thereof.

A use amount of the additives may be controlled depending on suitable or desired properties.

In some embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyltriethoxysilane, vinyl trichlorosilane, vinyltris(β-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but is not limited thereto.

The semiconductor photoresist composition may be formed into a pattern having a high aspect ratio without a collapse. Accordingly, in order to form a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, about 5 nm to about 20 nm, or about 5 nm to about 10 nm, the semiconductor photoresist composition may be used for a photoresist process using light in a wavelength ranging from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some embodiments may be used to realize extreme ultraviolet lithography using an EUV light source of a wavelength of about 13.5 nm.

According to some embodiments, a method of forming patterns using the aforementioned semiconductor photoresist composition is provided. For example, the manufactured pattern may be a photoresist pattern.

The method of forming patterns according to some embodiments includes forming an etching-objective layer on a substrate, coating the semiconductor photoresist composition on the etching-objective layer to form a photoresist layer, patterning the photoresist layer to form a photoresist pattern, and etching the etching-objective layer using the photoresist pattern as an etching mask.

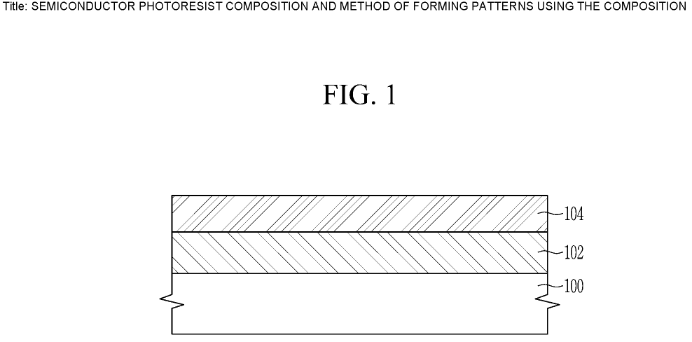

Hereinafter, a method of forming patterns using the semiconductor photoresist composition is described referring to FIGS. 1-5. FIGS. 1-5 are cross-sectional views for explaining a method of forming patterns using a semiconductor photoresist composition according to some embodiments.

Referring to FIG. 1, an object for etching is prepared. The object for etching may be a thin film 102 formed on a semiconductor substrate 100. Hereinafter, the object for etching is limited to the thin film 102. A whole surface of the thin film 102 is washed to remove impurities and/or the like remaining thereon. The thin film 102 may be for example a silicon nitride layer, a polysilicon layer, and/or a silicon oxide layer.

Subsequently, the resist underlayer composition for providing a resist underlayer 104 is spin-coated on the surface of the washed thin film 102. However, the embodiments are not limited thereto, and various suitable coating methods, for example a spray coating, a dip coating, a knife edge coating, a printing method, for example an inkjet printing and/or a screen printing, and/or the like may be used.

The coating process of the resist underlayer may be omitted, and hereinafter, a process including a coating of the resist underlayer is described.

Then, the coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity and pattern-forming capability of a photoresist line width if a ray reflected from on the interface between the substrate 100 and the photoresist layer 106 or a hardmask between layers is scattered into an unintended photoresist region.

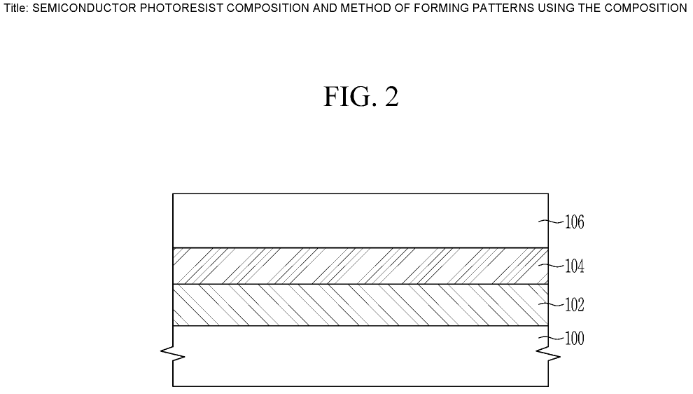

Referring to FIG. 2, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

For example, the formation of a pattern by using the semiconductor photoresist composition may include coating the semiconductor photoresist composition on the substrate 100 having the thin film 102 through spin coating, slit coating, inkjet printing, and the like and then, drying it to form the photoresist layer 106.

The semiconductor photoresist composition has already been illustrated in detail and will not be illustrated again.

Subsequently, a substrate 100 having the photoresist layer 106 is subjected to a first baking process. The first baking process may be performed at about 80° C. to about 120° C.

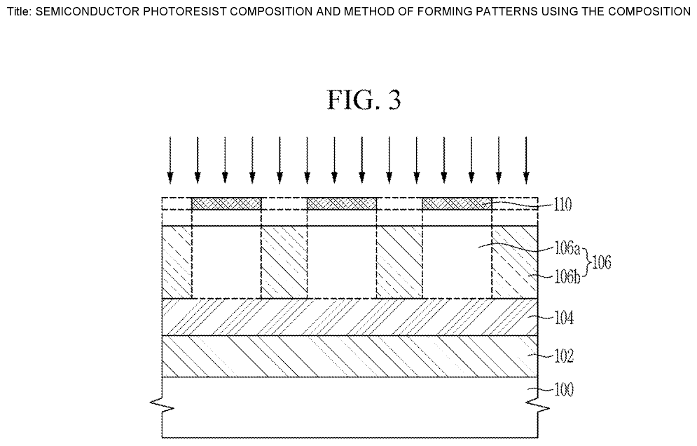

Referring to FIG. 3, the photoresist layer 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like as well as a short wavelength such as an i-line (a wavelength of about 365 nm), a KrF excimer laser (a wavelength of about 248 nm), an ArF excimer laser (a wavelength of about 193 nm), and/or the like.

For example, light for the exposure according to some embodiments may have a short wavelength in a range from about 5 nm to about 150 nm and a high energy wavelength, for example, EUV (Extreme UltraViolet; a wavelength of about 13.5 nm), an E-Beam (an electron beam), and/or the like.

The exposed region 106b of the photoresist layer 106 has a different solubility from the unexposed region 106a of the photoresist layer 106 by forming a polymer by a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist layer 106 becomes easily indissoluble regarding a developer due to the second baking process.

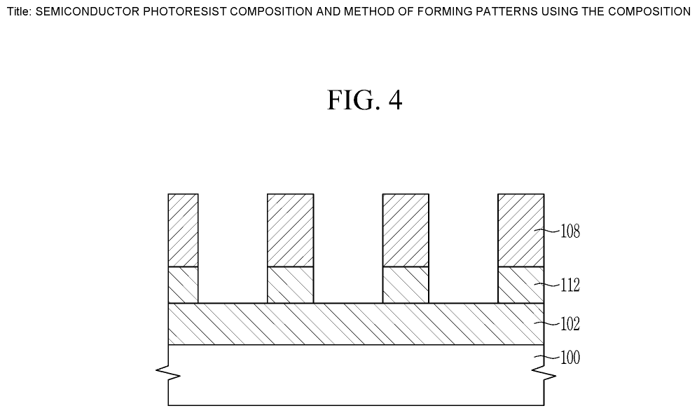

In FIG. 4, the unexposed region 106a of the photoresist layer is dissolved and removed using the developer to form a photoresist pattern 108. For example, the unexposed region 106a of the photoresist layer is dissolved and removed by using an organic solvent such as 2-heptanone and/or the like to complete the photoresist pattern 108 corresponding to the negative tone image.

As described above, a developer used in a method of forming patterns according to some embodiments may be an organic solvent. The organic solvent used in the method of forming patterns according to some embodiments may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some embodiments is not necessarily limited to the negative tone image but may be formed to have a positive tone image. Herein, a developing agent used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (Extreme UltraViolet; a wavelength of about 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm or about 5 nm to about 10 nm.

The photoresist pattern 108 may have a pitch of having a half-pitch of less than or equal to about 50 nm, for example less than or equal to about 40 nm, less than or equal to about 30 nm, less than or equal to about 20 nm, or less than or equal to about 10 nm and a line width roughness of less than or equal to about 5 nm, less than or equal to about 3 nm, less than or equal to about 2 nm, or less than or equal to about 1 nm.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

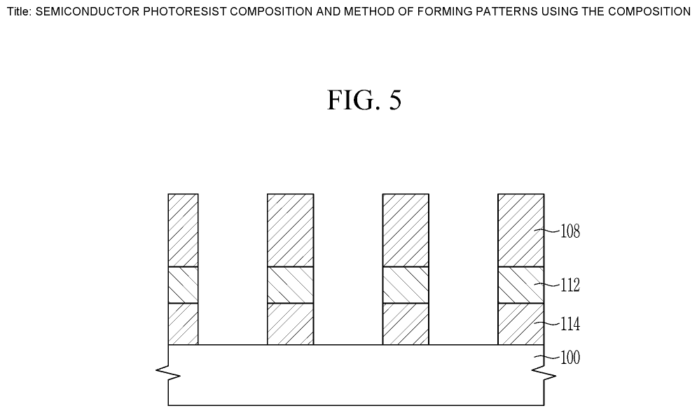

Referring to FIG. 5, the photoresist pattern 108 is applied as an etching mask to etch the exposed thin film 102. As a result, the thin film is formed with a thin film pattern 114.

The etching of the thin film 102 may be for example dry etching using an etching gas and the etching gas may be for example CHF₃, CF₄, Cl₂, BCl₃, and/or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of about 5 nm to about 100 nm which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, and about 5 nm to about 20 nm, or, for example, less than or equal to about 20 nm, like that of the photoresist pattern 108.

Hereinafter, embodiments of the present disclosure will be described in more detail through examples of the preparation of the aforementioned semiconductor photoresist composition. However, the present disclosure is technically not restricted by the following examples.

### Synthesis of Organometallic Compound

### Synthesis Example 1

In a 100 mL Schlenk flask, 10 g (25.5 mmol) of tbutyl trisdiethylamido tin was added to 10 mL of anhydrous dichloromethane and then, stirred at 0° C. under a nitrogen atmosphere.

Subsequently, a solution prepared by dissolving 5.7 g (78 mmol) of acetoneoxime in 16 mL of anhydrous dichloromethane was slowly added thereto at 0° C. The obtained mixture was stirred for 3 hours at room temperature and then, concentrated under a reduced pressure to remove dichloromethane and diethyl amine, thereby obtaining a compound represented by Chemical Formula 1a.

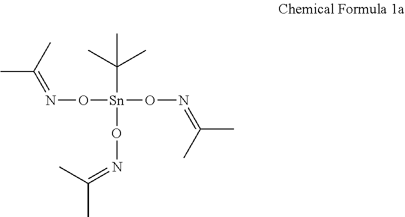 [SMILES: CC(C)=N[O][Sn]([O]N=C(C)C)([O]N=C(C)C)[C](C)(C)C]

### Synthesis Example 2

In a 100 mL Schlenk flask, 10 g (25.5 mmol) of tbutyl trisdiethylamido tin was added to 10 mL of anhydrous dichloromethane and then, stirred at 0° C. under a nitrogen atmosphere.

Subsequently, a solution prepared by dissolving 10.4 g (78 mmol) of tbutyl-N-hydroxycarbamate in 16 mL of anhydrous dichloromethane was slowly added thereto at 0° C. The obtained mixture was stirred at room temperature for 3 hours and then, concentrated under a reduced pressure to remove dichloromethane and diethyl amine, and a solid therefrom was recrystallized in n-hexane, thereby obtaining a compound represented by Chemical Formula 1b.

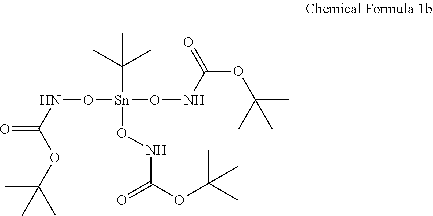 [SMILES: CC(C)(C)OC(=O)N[O][Sn]([O]NC(=O)OC(C)(C)C)([O]NC(=O)OC(C)(C)C)[C](C)(C)C]

### Synthesis Example 3

In a 100 mL Schlenk flask, 5.8 g (78 mmol) of acetohydroxamic acid was added to 16 mL of anhydrous dichloromethane and then, stirred at 0° C. under a nitrogen atmosphere.

Subsequently, a solution prepared by dissolving 10 g (25.5 mmol) of t-butyl-N-hydroxycarbamate in 10 mL of anhydrous dichloromethane was slowly added thereto at 0° C. The obtained mixture was stirred at room temperature for 3 hours and then, concentrated under a reduced pressure to remove dichloromethane and diethyl amine, and a solid therefrom was recrystallized in dichloromethane/normal hexane, thereby obtaining a compound represented by Chemical Formula 1c.

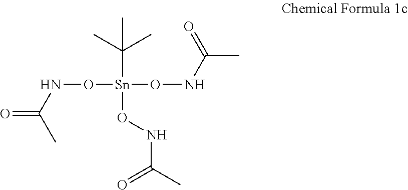 [SMILES: CC(=O)N[O][Sn]([O]NC(C)=O)([O]NC(C)=O)[C](C)(C)C]

### Synthesis Example 4

In a 100 mL Schlenk flask, 1.43 g (19.5 mmol) of acetoneoxime was added to 20 mL of anhydrous tetrahydrofuran and then, stirred at 0° C. under a nitrogen atmosphere. Subsequently, 0.45 g (19.5 mmol) of sodium pieces was slowly added thereto and then, reacted. The resultant was stirred at 0° C. for 30 minutes. Then, a solution prepared by dissolving 5 g (9.75 mmol) of triphenylantimony dibromide in 30 mL of anhydrous toluene was slowly added thereto.

The reaction solution was stirred at 70° C. under a nitrogen atmosphere for 12 hours. The reaction solution was cooled down to room temperature and Celite-filtered, a filtrate therefrom was concentrated under a reduced pressure, and a solid therefrom was recrystallized with dichloromethane/normal hexane, thereby obtaining a compound represented by Chemical Formula 1d.

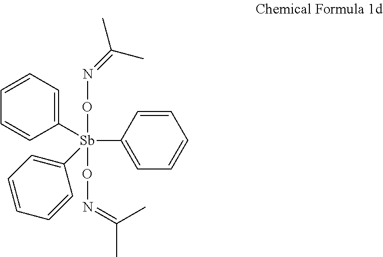

### Synthesis Example 5

In a 100 mL Schlenk flask, 2.6 g (19.5 mmol) of tbutyl-N-hydroxycarbamate was dissolved in 20 mL of anhydrous tetrahydrofuran and then, cooled to 0° C. and stirred under nitrogen. Subsequently, 0.45 g (19.5 mmol) of sodium pieces was slowly added thereto for a reaction.

The obtained resultant was stirred at 0° C. for 30 minutes. Subsequently, a solution prepared by dissolving 5 g (9.75 mmol) of triphenylantimony dibromide in 30 mL of anhydrous toluene was slowly added thereto.

The reaction solution was cooled under a nitrogen atmosphere at 70° C. for 12 hours. Then, the reaction solution was cooled to room temperature and Celite-filtered, a filtrate therefrom was concentrated, and a solid therefrom was dissolved in dichloromethane and recrystallized with normal hexane, thereby obtaining a compound represented by Chemical Formula 1e.

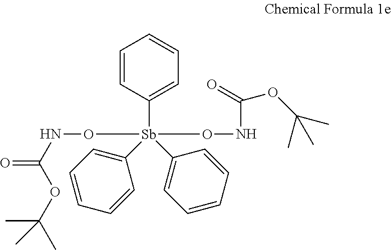

### Comparative Synthesis Example 1

nBuSnCl₃ (8.5 g, 30 mmol) was dissolved in anhydrous pentane and then, cooled to 0° C. Subsequently, triethylamine (10.0 g, 99 mmol) was slowly added thereto in a dropwise fashion, and ethanol (4.2 g, 90 mmol) was added thereto and then, stirred at room temperature for 5 hours. When a reaction was completed, the resultant was filtered, concentrated, and vacuum-dried, thereby obtaining a compound represented by Chemical Formula 4.

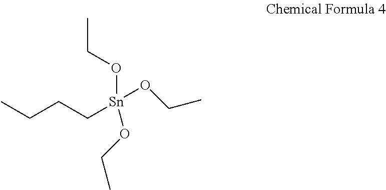

### Comparative Synthesis Example 2

A compound represented by Chemical Formula 5 was obtained in substantially the same manner as in Comparative Synthesis Example 1 except that BnSnCl₃ was used instead of nBuSnCl₃.

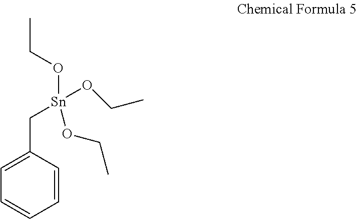 [SMILES: CC[O][Sn]([CH2]c1ccccc1)([O]CC)[O]CC]

### Preparation of Semiconductor Photoresist Composition

### Examples 1 to 5 and Comparative Examples 1 and 2

The compounds represented by Chemical Formulas 1a to 1e according to Synthesis Examples 1 to 5 and the compounds represented by Chemical Formulas 4 and 5 according to Comparative Synthesis Examples 1 and 2 were respectively dissolved in PGMEA (propylene glycol monomethyl ether acetate) at 3 wt % and then, filtered with a 0.1 μm PTFE syringe filter, thereby preparing photoresist compositions.

### Evaluation 1: Evaluation of Sensitivity and Line Edge Roughness (LER)

A linear array of 50 disk pads each having a diameter of 500 μm was irradiated into a wafer coated with each photoresist composition of Examples 1 to 5 and Comparative Examples 1 and 2 by using EUV ray (Lawrence Berkeley National Laboratory Micro Exposure Tool, MET). Exposure times of the pads were adjusted to apply an increased EUV dose to each pad.

Then, the resist and the substrate were exposed and baked (post-exposure bake, PEB) on a hotplate at 160° C. for 120 seconds. After the baked film was immersed in a developer (2-heptanone) for 30 seconds each, it was washed with the same developer for an additional 10 seconds to form a negative tone image, that is, to remove an unexposed coating portion. Finally, the resultant was baked on a 150° C. hot plate for 2 minutes to complete a process.

A residual resist thickness of the exposed pads was measured utilizing an Ellipsometer. The residual thickness was measured depending on each exposure dose and calculated therewith as a function to obtain Dg (an energy level where a development was complete), and the results are shown in Table 1.
※ Evaluation criteria (Dg value)
A: less than 16 mJ/cm²
B: greater than or equal to 16 mJ/cm²

### Evaluation 2: Evaluation of Storage Stability

The organometallic compounds according to Examples 1 to 5 and Comparative Examples 1 and 2 were evaluated with respect to storage stability, and the results are shown in Table 1.

### Storage Stability

The semiconductor photoresist compositions according to Examples 1 to 5 and Comparative Examples 1 and 2 were evaluated with respect to a degree of precipitation when left for a predetermined period at room temperature (20±5° C.) with naked eyes according to the following criteria.
※ Evaluation criteria
∘: can be stored for more than 1 month
Δ: can be stored for 1 week to less than 1 month
X: can be stored for less than 1 week

TABLE 1

| | Organic metallic | Storage | Dg |
|---|---|---|---|
| | compound | stability | (mJ/cm²) |
| Example 1 | Chemical Formula 1a | Δ | A |
| Example 2 | Chemical Formula 1b | ◯ | A |
| Example 3 | Chemical Formula 1c | ◯ | A |
| Example 4 | Chemical Formula 1d | ◯ | A |
| Example 5 | Chemical Formula 1e | ◯ | A |
| Comparative Example 1 | Chemical Formula 4 | X | B |
| Comparative Example 2 | Chemical Formula 5 | X | B |

Referring to the result of Table 1, the semiconductor photoresist compositions according to the examples exhibited excellent sensitivity and also, significantly improved storage stability, compared with the semiconductor photoresist compositions according to the comparative examples.

Hereinbefore, the certain embodiments of the present disclosure have been described and illustrated, however, it should be apparent to a person with ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Description of Symbols

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

1. A semiconductor photoresist composition, comprising:
an organometallic compound represented by Chemical Formula 1; and
a solvent:
(R¹)ₙ-M-Xₘ Chemical Formula 1
wherein, in Chemical Formula 1,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, or —R^{a}—O—R^{b}, wherein R^{a} is a substituted or unsubstituted C1 to C20 alkylene group and R^{b} is a substituted or unsubstituted C1 to C20 alkyl group,
M is a metal selected from Groups 2 to 16 of the periodic table,
n and m are each independently one selected from integers from 1 to 6, 2≤n+m≤6, and
X is a ligand represented by at least one selected from Chemical Formula 1A and Chemical Formula 1B, 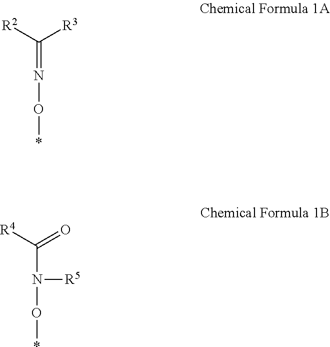
wherein, in Chemical Formula 1A and Chemical Formula 1B,
R², R³, and R⁵ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C1 to C30 acyl group, or a combination thereof,
R² and R³ are independently present or combined with each other to form a ring,
R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C6 to C30 aryloxy group, or a combination thereof, and
* is a linking point with M.

2. The semiconductor photoresist composition as claimed in claim 1, wherein:
the organometallic compound is represented by Chemical Formula 2 or Chemical Formula 3: 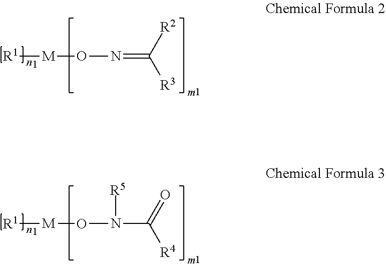
wherein, in Chemical Formula 2 and Chemical Formula 3,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),
M is a metal selected from Groups 2 to 16 of the periodic table,
n1 and m1 are each independently one selected from integers from 1 to 5, 2≤n1+m1≤6, and
R², R³, and R⁵ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C1 to C30 acyl group, or a combination thereof,
R² and R³ are independently present or combined with each other to form a ring, and
R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C6 to C30 arylalkyl group, a substituted or unsubstituted C1 to C20 alkoxy group, a substituted or unsubstituted C6 to C30 aryloxy group, or a combination thereof.

3. The semiconductor photoresist composition as claimed in claim 1, wherein:
n+m is an integer of 4 to 6.

4. The semiconductor photoresist composition as claimed in claim 1, wherein:
M is Sn or Sb.

5. The semiconductor photoresist composition as claimed in claim 1, wherein:
R², R³, and R⁵ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C2 to C30 heteroaryl group, a substituted or unsubstituted C1 to C20 alkoxy group, a substituted or unsubstituted C6 to C30 aryl group, a substituted or unsubstituted C1 to C30 acyl group, or a combination thereof, and
R² and R³ are independently present or combined with each other to form a ring.

6. The semiconductor photoresist composition as claimed in claim 1, wherein:
R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C2 to C30 heteroaryl group, a substituted or unsubstituted C1 to C20 alkoxy group, a substituted or unsubstituted C6 to C30 aryl group, a substituted or unsubstituted C1 to C30 aryloxy group, or a combination thereof.

7. The semiconductor photoresist composition as claimed in claim 1, wherein:
R¹ is a substituted or unsubstituted C1 to C20 alkyl group, a substituted or unsubstituted C3 to C20 cycloalkyl group, or a substituted or unsubstituted C6 to C30 aryl group,
R², R³, and R⁵ are each independently hydrogen, a substituted or unsubstituted C1 to C20 alkyl group, or a substituted or unsubstituted C3 to C20 cycloalkyl group, and
R⁴ is a substituted or unsubstituted C1 to C20 alkyl group, or a substituted or unsubstituted C3 to C20 cycloalkyl group.

8. The semiconductor photoresist composition as claimed in claim 1, wherein:
R¹ is a substituted or unsubstituted C3 to C20 branched alkyl group.

9. The semiconductor photoresist composition as claimed in claim 1, wherein:
R¹ is an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

10. The semiconductor photoresist composition as claimed in claim 1, wherein:
the organometallic compound is one selected from the compounds listed in Group 1:

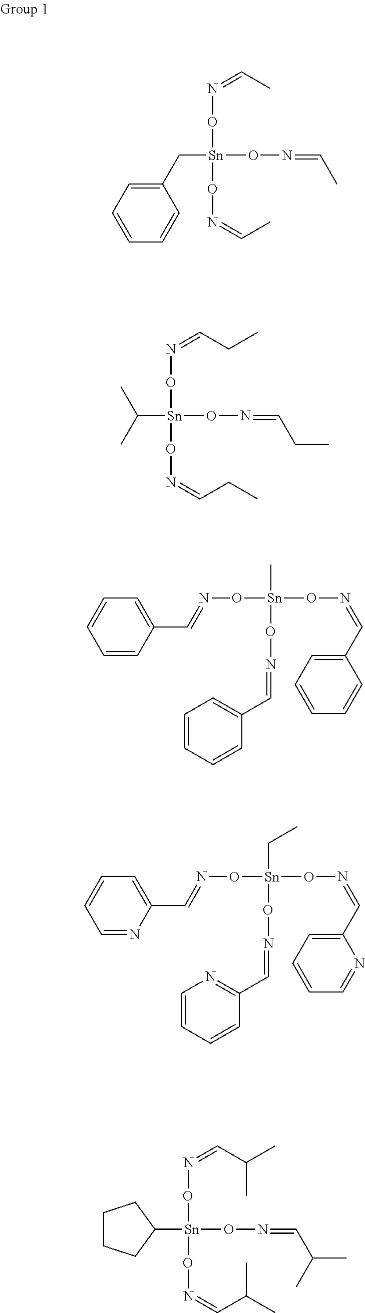

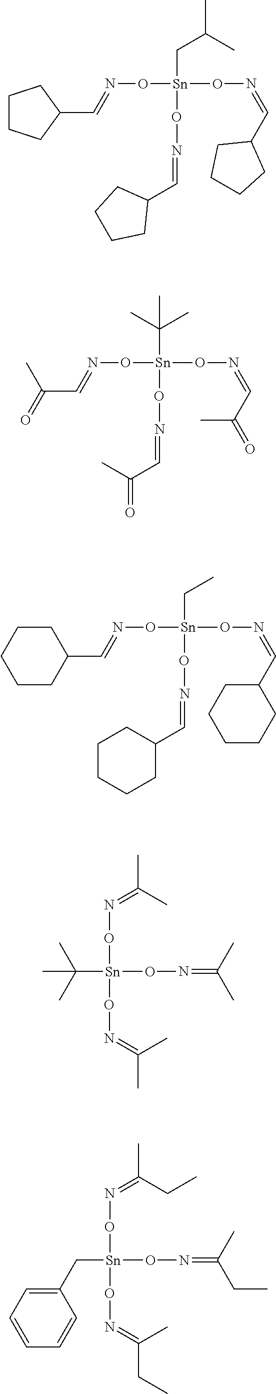 [SMILES: CC(C)[CH2][Sn]([O]N=CC1CCCC1)([O]/N=C\C1CCCC1)[O]/N=C/C1CCCC1 ; CC(=O)C=N[O][Sn]([O]/N=C\C(C)=O)([O]/N=C/C(C)=O)[C](C)(C)C ; C[CH2][Sn]([O]N=CC1CCCCC1)([O]/N=C\C1CCCCC1)[O]/N=C/C1CCCCC1 ; CC(C)=N[O][Sn]([O]N=C(C)C)([O]N=C(C)C)[C](C)(C)C ; CCC(C)=N[O][Sn]([CH2]c1ccccc1)([O]/N=C(/C)CC)[O]/N=C(\C)CC]

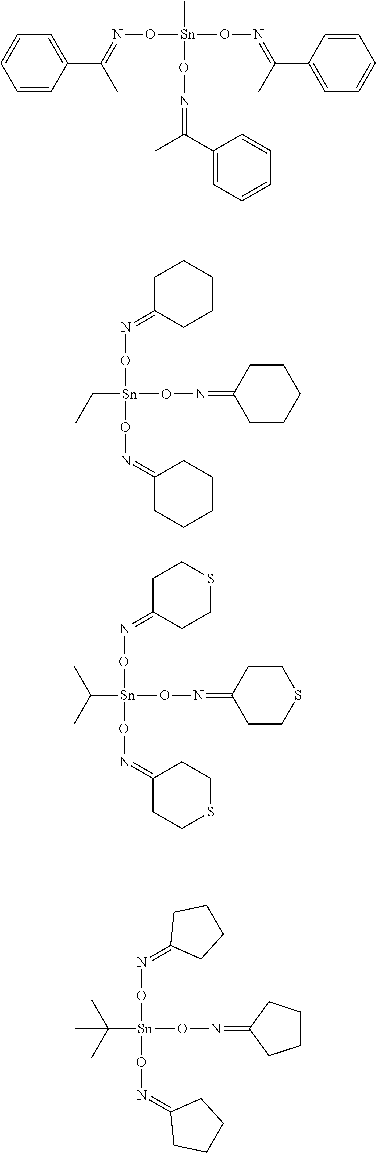

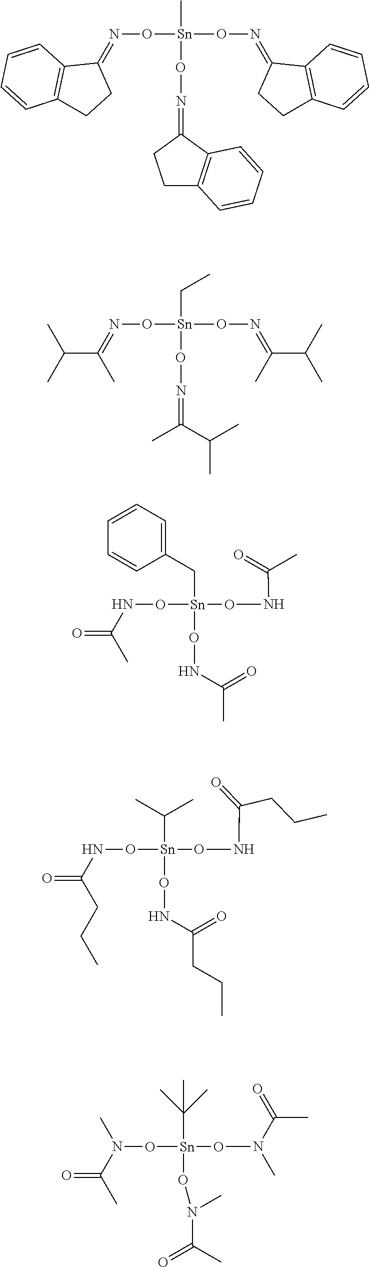 [SMILES: [CH3][Sn]([O]N=C1CCc2ccccc21)([O]/N=C1\CCc2ccccc21)[O]/N=C1\CCc2ccccc21 ; C[CH2][Sn]([O]N=C(C)C(C)C)([O]/N=C(\C)C(C)C)[O]/N=C(\C)C(C)C ; CC(=O)N[O][Sn]([CH2]c1ccccc1)([O]NC(C)=O)[O]NC(C)=O ; CCCC(=O)N[O][Sn]([O]NC(=O)CCC)([O]NC(=O)CCC)[CH](C)C ; CC(=O)N(C)[O][Sn]([O]N(C)C(C)=O)([O]N(C)C(C)=O)[C](C)(C)C]

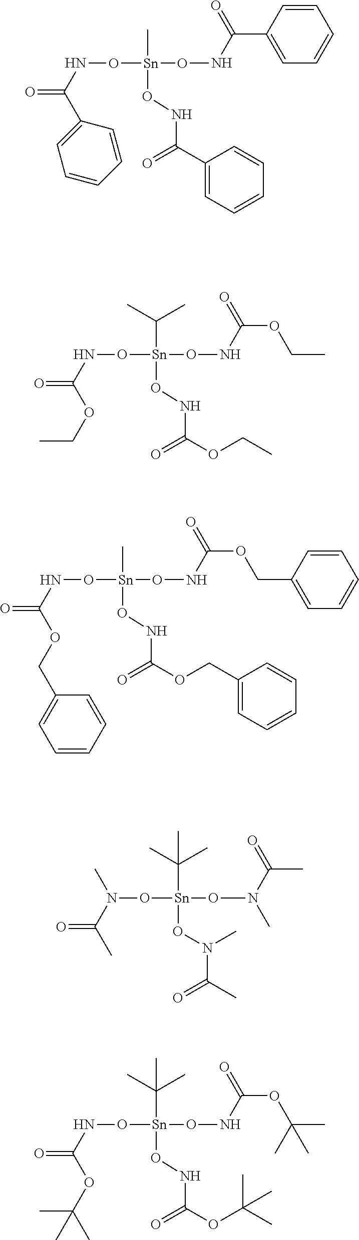 [SMILES: [CH3][Sn]([O]NC(=O)c1ccccc1)([O]NC(=O)c1ccccc1)[O]NC(=O)c1ccccc1 ; CCOC(=O)N[O][Sn]([O]NC(=O)OCC)([O]NC(=O)OCC)[CH](C)C ; [CH3][Sn]([O]NC(=O)OCc1ccccc1)([O]NC(=O)OCc1ccccc1)[O]NC(=O)OCc1ccccc1 ; CC(=O)N(C)[O][Sn]([O]N(C)C(C)=O)([O]N(C)C(C)=O)[C](C)(C)C ; CC(C)(C)OC(=O)N[O][Sn]([O]NC(=O)OC(C)(C)C)([O]NC(=O)OC(C)(C)C)[C](C)(C)C]

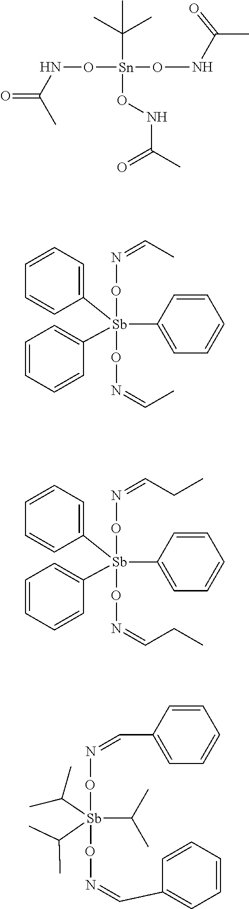

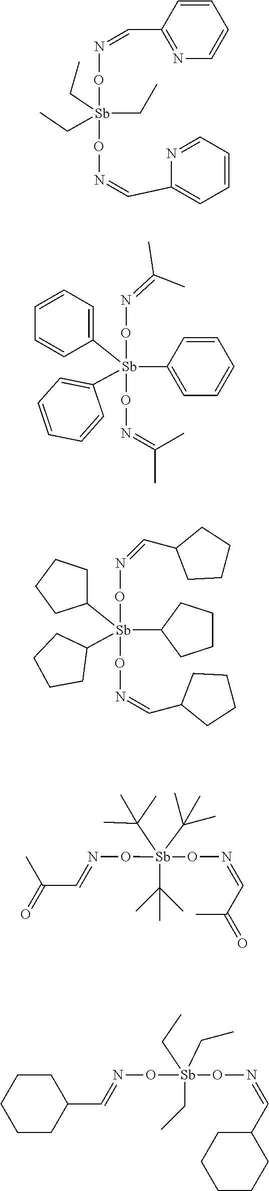

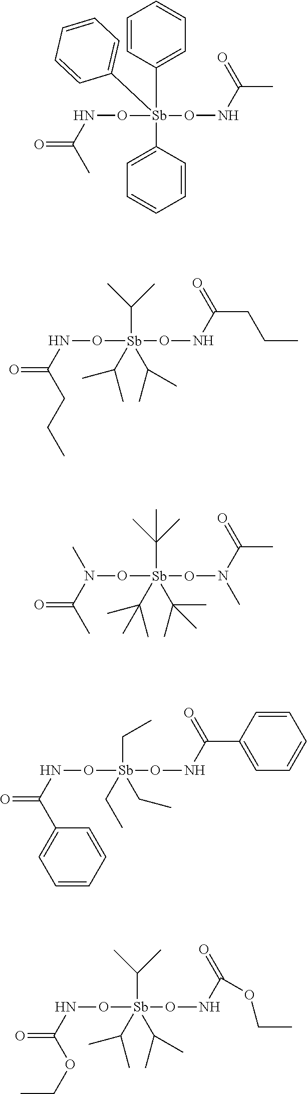

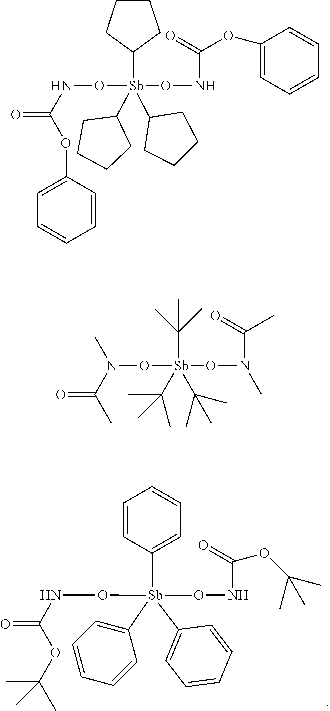

11. The semiconductor photoresist composition as claimed in claim 1, wherein:
based on 100 wt % of the semiconductor photoresist composition, the organometallic compound is included in an amount of about 1 wt % to about 30 wt %.

12. The semiconductor photoresist composition as claimed in claim 1, wherein:
the semiconductor photoresist composition further includes an additive of a surfactant, a crosslinking agent, a leveling agent, or a combination thereof.

13. A method of forming patterns comprising:
forming an etching-objective layer on a substrate;
coating the semiconductor photoresist composition as claimed in claim 1 on the etching-objective layer to form a photoresist layer;
patterning the photoresist layer to form a photoresist pattern; and
etching the etching-objective layer using the photoresist pattern as an etching mask.

14. The method as claimed in claim 13, wherein:
the photoresist pattern is formed using light having a wavelength of about 5 nm to about 150 nm.

15. The method as claimed in claim 13, wherein:
the photoresist pattern has a width of about 5 nm to about 100 nm.
